(19) United States
(12) Patent Application Publication
(10) Pub. No.: US 2026/0088805 A1
(43) Pub. Date: Mar. 26, 2026

(54) DIGITAL FILTER CIRCUIT FOR COMPUTING EXPONENTIAL VARIANCE OF A SIGNAL, CORRESPONDING SYSTEM-ON-CHIP AND METHOD OF OPERATION

(71) Applicant: STMicroelectronics International N.V., Geneva (CH)

(72) Inventors: Roberta Priolo, Milano (IT); Giovanni Amedeo Cirillo, Torino (IT); Carlo Porcaro, Reggio Calabria (IT)

(21) Appl. No.: 19/335,919

(22) Filed: Sep. 22, 2025

(30) Foreign Application Priority Data
Sep. 25, 2024 (IT) 102024000021350

(51) Int. Cl. H03H 17/02; H03H 17/00; H03H 17/06

(52) U.S. Cl. CPC H03H 17/0211; H03H 17/06; H03H 2017/0081

(57) ABSTRACT

A method of digital signal processing includes applying a first infinite impulse response filtering operation to a digital input signal to produce a first filtered signal, performing a mathematical transformation on a combination of the digital input signal and the first filtered signal to produce a transformed signal, applying a second infinite impulse response filtering operation to the transformed signal to produce a second filtered signal, performing a scaling operation on the second filtered signal to produce a scaled signal, and combining the second filtered signal and the scaled signal to produce a digital output signal indicative of a statistical property of the digital input signal.

### CROSS-REFERENCE TO RELATED APPLICATIONS

This application claims the benefit of Italian Application No. 102024000021350, filed on Sep. 25, 2024, which application is hereby incorporated herein by reference.

### TECHNICAL FIELD

The description relates to a digital filter circuit for computing exponential variance of a signal, corresponding system-on-chip and method of operation.

### BACKGROUND

In the field of inductive wireless power transmission, ASK modulation may be used for exchanging data between a power transmitter device PTx (i.e., the charger device) and a power receiver device PRx (i.e., usually a portable electronic device such as a mobile phone, tablet, or the like).

FIG. 1 is an example of a diagram of a wireless power transmission system, which includes a charging pad 10 that receives electrical energy from the power mains via a power cable 12, and a portable electronic device 14 (e.g., a smart phone) that includes a battery that can be inductively charged by the charging pad 10. To this effect, the charging pad 10 includes a power-transmitting coil 10a, and the device 14 includes a power-receiving coil 14a, which are configured to be inductively coupled when the portable device 14 is laid on the charging pad 10. Both coils 10a and 14a are depicted in FIG. 1 as separate elements from the pad 10 and the device 14 just for the sake of explanation.

The power transmitter 10 generates an alternating current (AC) in the power-transmitting coil 10a to induce a time-varying magnetic field through the power-receiving coil 14a. Some standards for wireless power transfer, such as the Qi standard, use a communication protocol to exchange data between the devices 10 and 14 to manage the charging process: further details on the Qi standard for wireless charging systems can be found in the Qi specification documents, version 1.3 of January 2021, publicly available at www.wirelesspowerconsortium.com. Substantially, in such communication protocols such as Qi, the power transmitter 10 can send messages to the power receiver 14 exploiting Frequency-Shift Keying (FSK) modulation, and the power receiver 14 can respond to the power transmitter 10 exploiting Amplitude-Shift Keying (ASK) modulation.

FIG. 2 is an example of a circuit diagram of some internal components of the devices 10 and 14 used for wireless power transmission (from device 10 to device 14, see the arrow labelled PT) and data exchange via ASK-based communication (from device 14 to device 10, see the arrow labelled DE). Substantially, the power transmitter 10 includes the coil 10a and an AC power source that supplies the coil 10a with an AC voltage. The AC power source may include a Pulse-Width Modulation (PWM) square wave generator 11 that controls a power inverter 13 to produce an AC voltage V_{AB}, which is then applied to the coil 10a via a series capacitor. The power receiver 14 includes the coil 14a inductively coupled with the coil 10a, a switchable capacitive network 15 arranged downstream of the coil 14a, a bridge rectifier circuit 16 (e.g., a diode bridge) arranged downstream of the switchable capacitive network 15, a parallel RC circuit 17 arranged at the output of the rectifier circuit 16, and a switchable load 18 (e.g., a resistor in series with an electronic switch) selectively couplable in parallel to the RC circuit 17.

The voltage at the power-transmitting coil 10a is a sinusoidal wave W (resulting from resonant filtering of the voltage V_{AB}) that carries the power to be transmitted to the power-receiving coil 14a. The power receiver device 14 is able to slightly change (modulate) the amplitude of the power carrier wave by changing its internal load impedance (e.g., by selectively coupling and decoupling the switchable load 18 to and from the RC circuit 17), and this mechanism (also known as backscatter modulation) is used to implement ASK modulation of the carrier wave to transmit information from the power receiver to the power transmitter side. The power transmitter device 10 can sense the voltage across the coil 10a (e.g., via an amplifier circuit 19a that produces an analog voltage signal V_{ASKD}, followed by an analog-to-digital converter (ADC) 19b that digitizes the signal V_{ASKD}) and demodulate the message sent by the power receiver device 14 (e.g., via an ASK demodulator circuit 19c, which may include for instance a digital I/Q demodulator) thus implementing ASK demodulation. Thus, the demodulation logic can be fully digital, using an ADC to monitor the voltage at coil 10a.

In particular, the Qi protocol may rely on a Manchester-like ASK encoding known as Biphase-Mark Code (BMC) as exemplified in FIG. 3, which shows the waveforms of a clock signal CLK with period t_{CLK} and a data signal DATA (obtained after ASK demodulation of the sinusoidal carrier wave). Substantially, the digital signal DATA is interpreted as carrying a ‘o’ bit if its value is constant (either high or low) during an entire clock cycle, while it is interpreted as carrying a ‘1’ bit if its value changes during a clock cycle (either a rising edge or a falling edge). Said otherwise, each bit of the original data is represented by two logical states, which together form one bit: each logical one is represented as a pair of two different bits (10 or 1), and each logical zero by a pair of equal bits (00 or 11). Each logic level at the beginning of a cell is reversed compared to the level at the end of the previous cell. According to the Qi protocol, the preamble may be given by a sequence of consecutive logic ones (whose number may practically depend on the bit rate), then the message is constituted by a start bit (always a logic zero), then one data byte, a parity bit set to 1 if the data byte contains an even number of 1 bits, finally a stop bit (always 1). According to the Qi protocol, the clock signal may have a frequency f_{CLK} of 2 kHz±4% (also corresponding to the bit rate).

The waveforms of an input modulated signal W and an output demodulated signal DATA of an ASK demodulator are shown again in FIG. 4. The modulated signal Wis assumed to be sampled by an ADC, so that the entire demodulation process can be carried out using digital hardware (e.g., inside the power transmitting device 10 as exemplified in FIG. 2).

FIG. 5 is an example of a circuit block diagram of the main blocks of the processing chain of an ASK demodulator circuit 50. An ADC 51 (which may or may not be considered to be a part of the ASK demodulator) receives the modulated analog signal W (or modulated stream) from the primary coil 10a, and converts signal W to an input digital signal x[n]. Signal x[n] is passed to a circuit 52 (band pass to baseband) that shifts the transmitted signal spectrum into the baseband domain (around DC). The output from the circuit 52 is passed to an image rejection filter circuit 53 that removes high-frequency artifacts generated by the previous circuit 52. The output from the filter circuit 53 is passed to a decimation circuit 54 that applies a decimation, since the bandwidth requirement is decreased. The output from the decimation circuit 54 is passed to a high-pass filter circuit 55 that removes the DC which usually emerges during the down-conversion operated by the decimation circuit 54. The output from the filter circuit 55 is passed to a slicer circuit 56 that accepts a signal which is usually symmetric to the 0, and carries out a binary decision based on a “threshold” parameter. Thus, the slicer 56 operates substantially as a hysteresis comparator, compressing information to multiple bits to a single one (two levels). The output from the slicer circuit 56 is passed to a symbol decoder circuit 57 that recognizes the message associated with ASK modulation and produces a digital demodulated signal DATA_out.

In some applications, it may be advantageous that the ASK demodulator includes a logic configured to recognize (detect) the presence of an amplitude modulation of the input signal. Detection of the presence of amplitude modulation can be accomplished by carrying out a demodulation and an energy estimation of the demodulated signal. In order to estimate the energy of a signal, the exponential variance of the signal can be computed, insofar as its value is indicative of the energy of the signal. The exponential variance (or exponentially-weighted variance, indicated herein as o²[n] or S[n]) of a digital signal x[n] can be computed according to the following equation:

$${σ}^{2} [ n ] = S [ n ] = ( 1 - α ) \cdot [ S [ n - 1 ] + α \cdot {( x [ n ] - μ [ n - 1 ] )}^{2} ]$$

where α is a parameter between 0 (included) and 1 (not included) and usually in the form α=2^{-k}, and μ[n] is the exponential average (or exponentially-weighted average) of signal x[n], which in turn can be expressed according to the following equation:

$$μ [ n ] = α \cdot x [ n ] + ( 1 - α ) \cdot μ [ n - 1 ]$$

It is therefore desirable that an ASK demodulator is configured to compute the exponential average and the exponential variance of the input digital signal, e.g., in order to detect the presence of ASK modulation of the input signal. According to some known solutions, the exponential moving variance can be computed by a firmware, but these solutions are usually affected by a long computation time. According to other known solutions, the exponential moving variance can be computed by a dedicated hardware IP block, but these solutions are usually affected by a high area overhead, the impossibility to reuse IP blocks that have been already validated, and the fact that the dedicated IP block can be used only for computing the exponential moving variance.

Various documents possibly of interest in the field of digital signal processing include US 2010/0109844 A, US 2020/0013421 A1, U.S. Pat. No. 5,823,964 A, US 2021/0314201 A1, US 2005/0210091 A1, and the article by M. A. Basiri M and N. M. Sk, “Configurable Folded IIR Filter Design”, in IEEE Transactions on Circuits and Systems II: Express Briefs, vol. 62, no. 12, pp. 1144-1148 Dec. 2015, doi: 10.1109/TCSII.2015.2468917.

### SUMMARY

Embodiments disclosed herein can provide improved hardware circuits (digital filters) for computing the exponential average and the exponential variance of a digital signal, which can be used in an ASK demodulator circuit and occupy less silicon area than the known solutions.

The description relates to digital filter circuits, which can be used for computing the exponential average and the exponential variance of a digital signal (e.g., for use in Amplitude-Shift Keying or ASK demodulator circuits).

One or more embodiments contribute in providing such improved hardware digital filter circuits, and corresponding system-on-chips and methods of operation.

One or more embodiments may relate to a corresponding system-on-chip (SoC).

One or more embodiments may relate to a corresponding method of operation.

According to an aspect of the present description, a digital filter circuit includes an input terminal configured to receive a digital input signal and an output terminal configured to produce a digital output signal. he digital output signal is indicative of an exponential moving variance of the digital input signal. The digital filter circuit includes a signal processing chain arranged between the input terminal and the output terminal. In the signal processing chain, low-pass filtering is applied to the digital input signal to produce a first intermediate signal indicative of the exponential moving average of the digital input signal. The first intermediate signal is subtracted from the digital input signal to produce a second intermediate signal. A square value of the second intermediate signal is computed to produce a third intermediate signal. Low-pass filtering is applied to the third intermediate signal to produce a fourth intermediate signal indicative of the exponential moving average of the third intermediate signal. The fourth intermediate signal is right-shifted to produce a fifth intermediate signal. The fifth intermediate signal is subtracted from the fourth intermediate signal to produce the digital output signal.

One or more embodiments may thus provide a digital filter circuit for computing the exponential variance of a signal, with low silicon area footprint.

According to another aspect of the present description, a system-on-chip (e.g., a controller for a wireless power transmitter) includes an analog-to-digital converter (ADC), a digital filter circuit according to one or more embodiments, and an ASK demodulator circuit. The ADC is configured to receive an analog amplitude-modulated signal and convert it to produce a digital input signal for the digital filter circuit. The digital filter circuit is configured to receive the digital input signal from the ADC and produce a digital output signal. The ASK demodulator circuit is configured to receive the digital output signal produced by the digital filter circuit.

According to another aspect of the present description, a method of operating a digital filter circuit according to one or more embodiments or a system-on-chip according to one or more embodiments includes: receiving a digital input signal at the input terminal; applying low-pass filtering to the digital input signal to produce a first intermediate signal indicative of the exponential moving average of the digital input signal; subtracting the first intermediate signal from the digital input signal to produce a second intermediate signal; computing a square value of the second intermediate signal to produce a third intermediate signal; applying low-pass filtering to the third intermediate signal to produce a fourth intermediate signal indicative of the exponential moving average of the third intermediate signal; right-shifting the fourth intermediate signal to produce a fifth intermediate signal; and subtracting the fifth intermediate signal from the fourth intermediate signal to produce the digital output signal at the output terminal.

### BRIEF DESCRIPTION OF THE DRAWINGS

One or more embodiments will now be described, by way of example only, with reference to the annexed figures, wherein:

FIG. 1 is an example of a diagram of a wireless power transmission system;

FIG. 2 is an example of a circuit diagram of some components of the devices of the wireless power transmission system of FIG. 1;

FIGS. 3 and 4 are time diagrams including waveforms of signals in an ASK demodulator circuit;

FIG. 5 is an example of a circuit block diagram of the main blocks of the processing chain of an ASK demodulator circuit;

FIG. 6 is an example of a circuit block diagram of a digital IIR DC-track filter;

FIG. 7 is an example of a diagram of the magnitude of the transfer function of the digital IIR DC-track filter of FIG. 6;

FIG. 8 is an example of an operation block diagram of a sequence of operations that can be performed to compute the exponential variance of a digital signal;

FIG. 9 is an example of an operation block diagram of another sequence of operations that can be performed to compute the exponential variance of a digital signal;

FIG. 10 is an example of a circuit block diagram of an architecture of a digital filter for computing the exponential variance of a digital signal according to one or more embodiments of the present description;

FIG. 11 is an example of a circuit block diagram of a folded architecture of a digital filter for computing the exponential variance of a digital signal according to one or more embodiments of the present description;

FIG. 12 is an example of a circuit block diagram of a modified digital IIR DC-track filter suitable for use in the digital filter of FIG. 11, according to one or more embodiments of the present description; and

FIG. 13 is an example of a circuit block diagram of an IP block that incorporates a digital filter for computing the exponential variance of a digital signal, according to one or more embodiments of the present description.

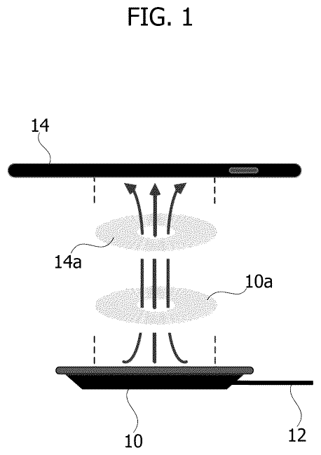

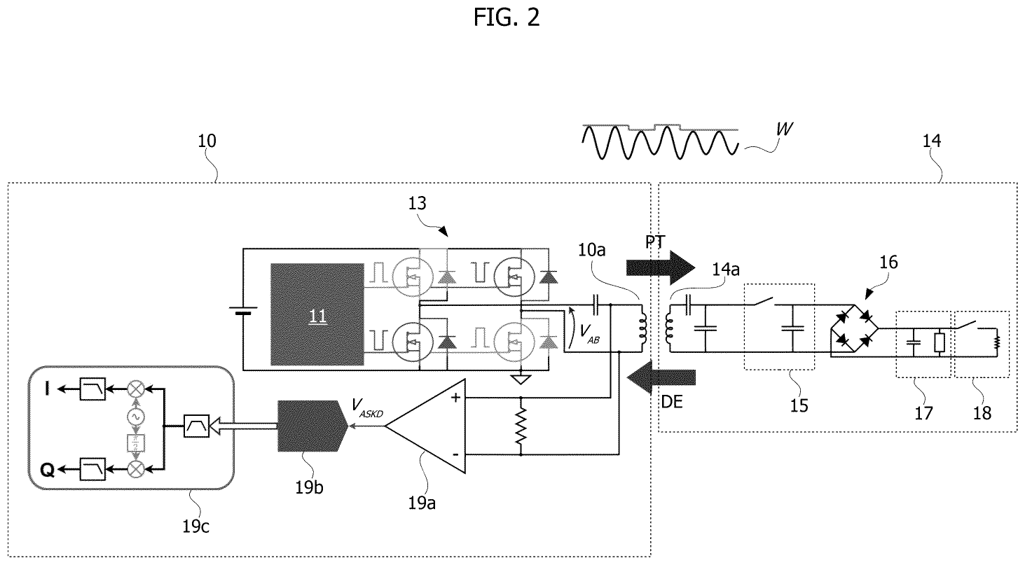

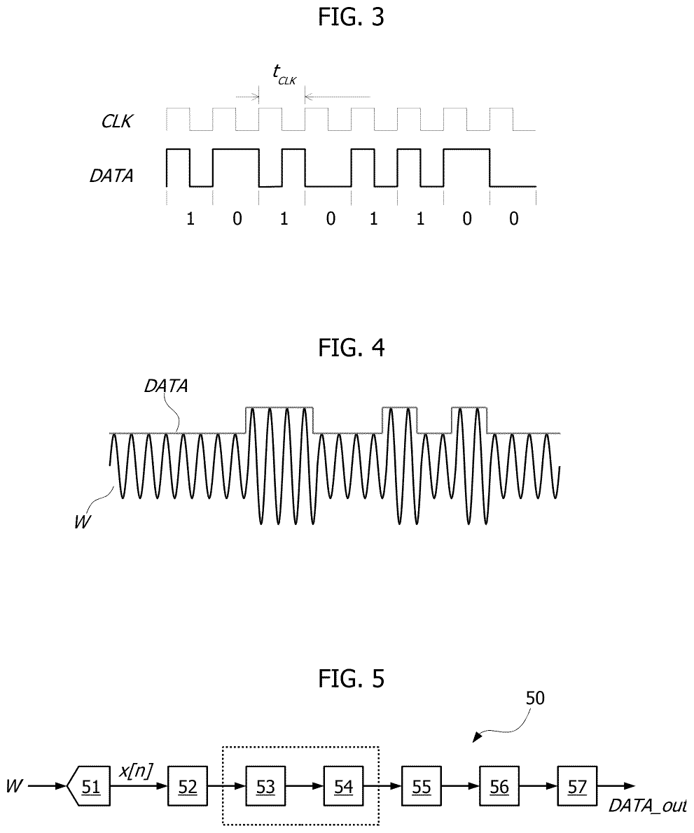

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

It is noted that the exponential average (μ[n]) and the exponential variance (o²[n] or S[n]) of a digital signal x[n] are ruled by equations that can be implemented by Infinite Impulse Response (IIR) digital filters. In order to compute μ[n] and o²[n] of an input signal, one or more embodiments may rely on the implementation of a low-area digital filter circuit that can be referred to as “IIR DC-track filter”.

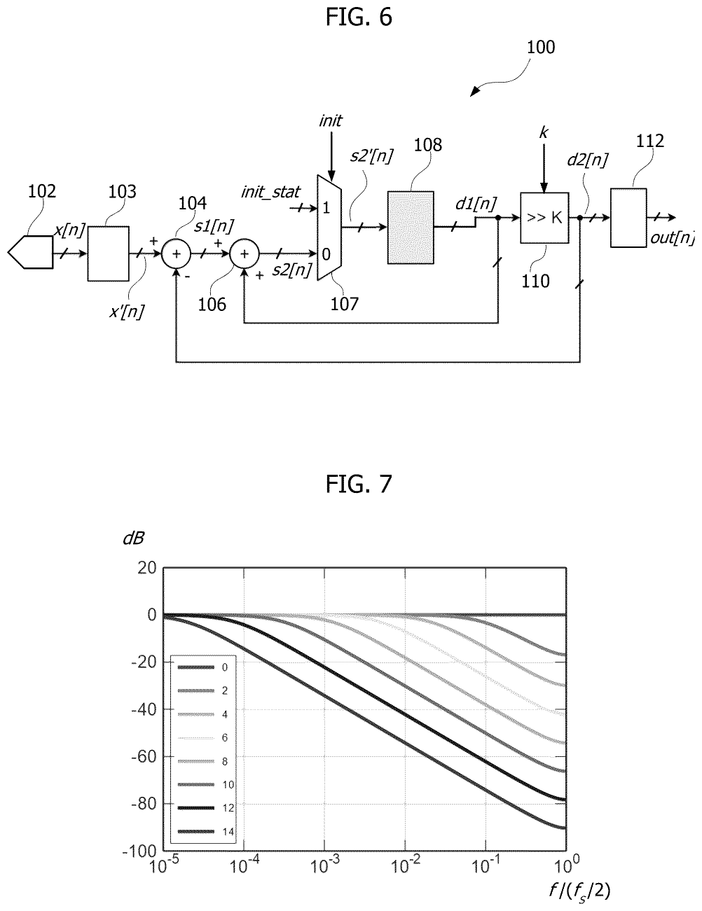

The architecture of a digital IIR DC-track filter 100 is reproduced in the circuit block diagram of FIG. 6. The filter 100 receives an input digital signal x[n] (e.g., a 16-bit signal) from an ADC 102. Optionally, the filter 100 may include a sign extension circuit 103 that receives the input signal x[n] and extends the sign of signal x[n], increasing its number of bits (e.g., from 16 bits to 32 bits), and producing a (replica) signal x′[n]. The filter 100 includes a subtractor circuit 104 that subtracts a feedback signal d2[n] (e.g., a 32-bit signal) from an output stage of the filter 100 from the signal x′[n] to produce a first intermediate signal s1[n] (e.g., a 32-bit signal). In one or more embodiments where the sign extension circuit 103 is not present, signal x[n] is directly passed to the subtractor circuit 104 instead of signal x′[n].

The filter 100 includes an adder circuit 106 that adds together the intermediate signal s1[n] and another feedback signal d1[n] (e.g., a 32-bit signal) coming from another output stage of the filter 100 to produce a second intermediate signal s2[n] (e.g., a 32-bit signal). Optionally, the filter 100 may include a multiplexer circuit 107 that receives the intermediate signal s2[n] at a first input and a register initialization signal init_stat (e.g., a 32-bit signal) at a second input. The multiplexer 107 is controlled by a control signal init. The multiplexer 107 and the related initialization circuitry may be used to force the value stored in a memory element 108 of the filter circuit 100 to a desired initial status at the initial stage of operation of the filter circuit 100.

The multiplexer 107 passes to its output, as a signal s2′[n] (e.g., a 32-bit signal), the register initialization signal init_stat if the control signal init is asserted, or passes to its output the intermediate signal s2[n] if the control signal init is de-asserted. In one or more embodiments where the initialization circuitry and the multiplexer 107 are not present, signal s2[n] is directly passed instead of signal s2′[n]. The filter 100 includes a memory element 108 (e.g., a flip-flop, FF) that receives the second intermediate signal s2[n] (or sz′[n]), stores the value of signal s2[n] (or s2′[n]) and passes it to its output as directed by a clock signal or enable signal of the filter circuit 100 (not visible in FIG. 6 for the sake of ease of illustration).

The output of the memory element 108 corresponds to the feedback signal d1[n] that is passed to the adder circuit 106. The filter 100 includes a right-shifter circuit 110 that receives signal d1[n] from the memory element 108 and a shift-control signal k (e.g., a 4-bit signal), and produces the signal d2[n] by right-shifting signal d1[n] by a number of bits as dictated by the decimal value of signal k. For instance, if signal k is a 4-bit signal, it can assume values in the range [0; 15], and the shifter circuit 110 can thus right-shift signal d1[n] by a minimum of 0 bits (i.e., no shifting) to a maximum of 15 bits. Substantially, operation of the shifter circuit 110 corresponds to multiplying the decimal value of signal d1[n] by a quantity α=2^{-k} (i.e., dividing by 2^{k}) to compute the decimal value of signal d2[n].

Optionally, the filter 100 includes a truncation circuit 112 that receives signal d2[n] and truncates it (e.g., discarding one or more bits starting from the least significant bit, LSB) to reduce its number of bits and produce the filter output signal out[n] (e.g., passing from a 32-bit signal to a 16-bit signal). Therefore, the transfer function of the digital IIR DC-track filter 100 can be written as follows:

$$H ( z ) = \frac{{2}^{- k} {z}^{- 1}}{1 - ( 1 - {2}^{- k} ) {z}^{- 1}}$$

$$k ∈ [ 0 ; 15 ]$$

Therefore, the filter circuit 100 implements an IIR (Infinite Impulse Response) structure that is based (only) on shift operations and addition/subtraction operations, hence it is very area efficient. For instance, in one or more embodiments the filter 100 may have an area lower than 1 kgate with a clock frequency in the range of MHz, when a 16-bit input signal is processed. The filter 100 can generate low-pass responses with a cutoff frequency that decreases as the value of signal k increases. In this respect, reference may be made to the diagram of FIG. 7, which shows the magnitude (in dB) of the transfer function of the filter 100 as a function of the normalized frequency f/(fₛ/2) (in absolute value) for different values of k, ranging from 0 to 14. The cutoff frequency can reach very low values; hence, this filter can be employed for computing the DC value of the input signal.

It is noted that the IIR DC-track filter 100 as exemplified in FIG. 6 substantially computes, at the output out[n], the exponential average of the input signal x[n] with a delay of one sample (see the term z⁻¹ in the numerator of the transfer function discussed above), that is, at a certain clock cycle during which the i^{th} data sample is available at the input x[n], the output out[n] is representative of the exponential average computed on the samples up to the (i−1)^{th} sample.

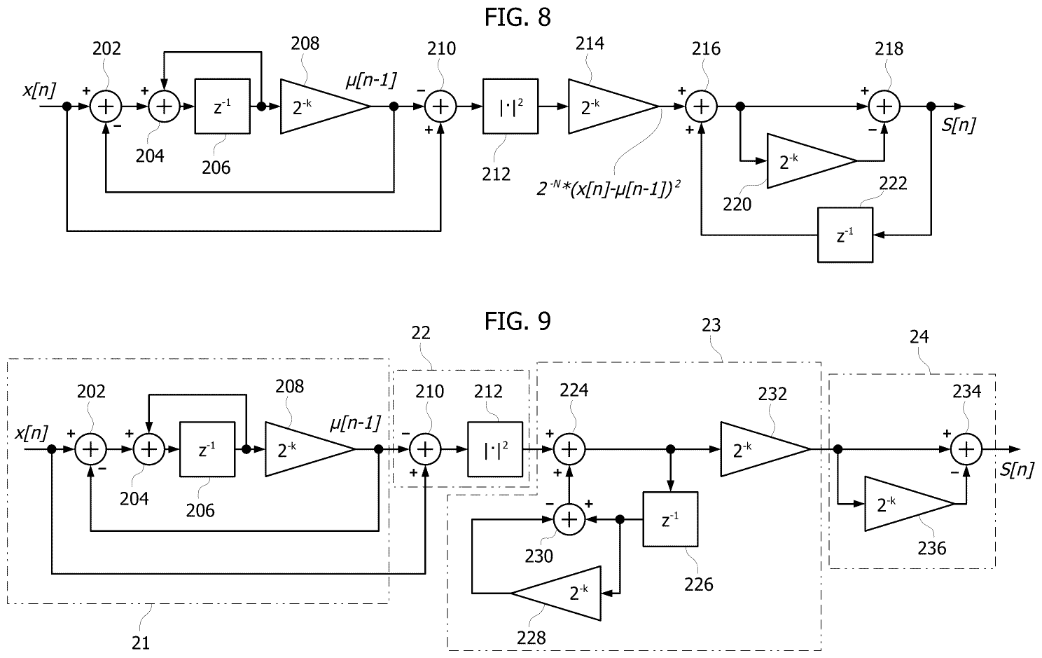

It is also noted that the sequence of operations that can be performed to compute the exponential variance S[n] of a digital signal x[n] can be expressed as indicated in the operation block diagram of FIG. 8, which includes (only) subtraction blocks, addition blocks, memory blocks (which store their input value at one clock cycle and release it at the next clock cycle, and are indicated as z⁻¹), shift blocks (which correspond to multiplications by 2^{-k} in the case of a right-shift, or multiplications by 2^{k} in the case of a left-shift), and square value blocks. The input signal is the digital data signal x[n].

A first block of operations includes a subtractor 202, an adder 204, a memory element 206 and a right-shifter 208, with two feedback loops, one from the output of the memory element 206 to an input of the adder 204, and the other from the output of the right-shifter 208 to the negative input of the subtractor 202. The output value of operations 202, 204, 206 and 208 is μ[n−1], i.e., it is equal to the exponential average of signal x[n] with a one-sample delay. A second block of operations takes μ[n−1] as input and includes a subtractor 210, a square operator 212 and a right-shifter 214 with one feedforward loop (from the input terminal to the positive input of the subtractor 210). The output value of operations 210, 212 and 214 is 2^{-k.} (x[n]−μ[n−1])². A third block of operations takes 2^{-k.}(x[n]−μ[n−1])² as input and includes an adder 216, a subtractor 218, a right-shifter 220 in a feedforward loop from the output of the adder 216 to the negative input of the subtractor 218, and a memory element 222 in a feedback loop from the output terminal to an input of the adder 216. The output value of operations 216, 218, 220 and 222 is the exponential variance S[n] of signal x[n].

It can be demonstrated that the sequence of operations exemplified in FIG. 8 is equivalent to the sequence of operations exemplified in the operation block diagram of FIG. 9, which also includes (only) subtraction blocks, addition blocks, memory blocks, shift blocks, and square value blocks, and also produces the exponential variance S[n] starting from an input digital signal x[n].

In the diagram of FIG. 9, the input signal is the digital data signal x[n]. A first block of operations 21 is the same as the first block of operations discussed with reference to FIG. 8, and thus includes a subtractor 202, an adder 204, a memory element and 206 a right-shifter 208, with two feedback loops, one from the output of the memory element 206 to an input of the adder 204, and the other from the output of the right-shifter 208 to the negative input of the subtractor 202. The output value of operations 202, 204, 206 and 208 is μ[n−1], i.e., it is equal to the exponential average with a one-sample delay. A second block of operations 22 takes μ[n−1] as input and includes the subtractor 210 and the square operator 212 with one feedforward loop (from the input terminal to the positive input of the subtractor 210).

Thus, the second block of operations 22 in FIG. 9 corresponds to the second block of operations in FIG. 8, but without the right-shifter 214. The output value of the second block of operations 22 is thus (x[n]−μ[n−1])². A third block of operations 23 takes (x[n]−μ[n−1])² as input and includes an adder 224, a memory element 226, a right-shifter 228, a subtractor 230 and a right-shifter 232 arranged as indicated in the Figure. The operations of block 23 compute the exponential average of signal (x[n]−μ[n−1])². A fourth block of operations 24 takes the exponential average of signal (x[n]−μ[n−1])² as input and includes a subtractor 234 and a right-shifter 236 in a feedforward loop from the output of the right-shifter 232 to the negative input of the subtractor 234. Thus, the block of operations 24 amounts to multiplying the exponential average of signal (x[n]−μ[n−1])² by (1−2^{-k}). The output value of the fourth block of operations 24 is the exponential variance S[n] of signal x[n].

Since the blocks of operations 21 and 23 both amount to the computation of the exponential average of their respective input signals, one or more embodiments may rely on the use of a DC-track filter 100 (e.g., as exemplified in FIG. 6) to carry out the operations of blocks 21 and 23: it is in fact recalled that the DC-track filter 100 computes the exponential moving average (delayed by one sample). Since the IIR DC-track filter 100 is used twice, the exponential variance S[n] has a delay of one sample with respect to the input data signal x[n]. Alternatively, one or more embodiments may rely on the use of a DC-track filter 100 to carry out the operations of block 21 (i.e., to compute the exponential average), and then carry out the remaining operations 210 to 222 as exemplified in FIG. 8 in order to compute the exponential variance.

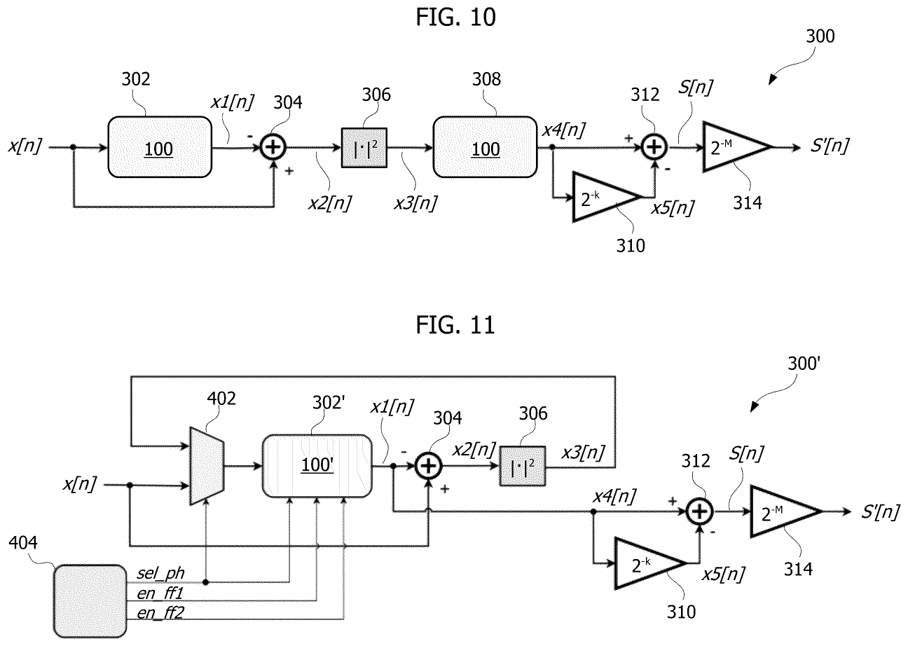

One or more embodiments may thus rely on a digital filter 300 having the architecture exemplified in the circuit block diagram of FIG. 10 in order to compute the exponential variance S[n] of signal x[n]. The digital filter 300 includes an input terminal that receives the data signal x[n]. A first instance 302 of a DC-track filter circuit 100 receives the signal x[n] at the input and produces a respective output signal x1[n], carrying out the operations of block 21 of FIG. 9. A subtractor circuit 304 subtracts signal x1[n] from signal x[n] and produces a respective output signal (difference signal) x2[n]. A square operator circuit 306 receives the signal x2[n] at the input and produces a respective output signal x3[n], corresponding to the squared value of signal x2[n]. It will be noted that circuits 304 and 306 carry out the operations of block 22 of FIG. 9.

A second instance 308 of a DC-track filter circuit 100 receives the signal x3[n] at the input and produces a respective output signal x4[n], carrying out the operations of block 23 of FIG. 9. A right-shifter circuit 310 receives the signal x4[n] at the input and right-shifts signal x4[n] by a number k of bits (i.e., multiplies by 2^{-k}) to produce a respective output signal x5[n]. A subtractor circuit 312 subtracts signal x5[n] from signal x4[n] and produces a respective output signal (difference signal) that corresponds to the exponential variance S[n] of signal x[n]. It will be noted that circuits 310 and 312 carry out the operations of block 24 of FIG. 9. Optionally, the digital filter 300 may also include a right-shifter circuit 314 that receives the exponential variance signal S[n] at the input and right-shifts signal S[n] by a number M of bits (i.e., multiplies by 2^{-M}) to produce an output signal S′[n]=2^{-M.}S[n]. This is an additional operation, that scales the exponential variance S[n] by 2^{-M}, thus producing an output signal from the hardware block 300 that can be represented on fewer bits.

Since the IIR DC-track filter 100 is used twice (sequentially, in two consecutive phases of the computation of the exponential variance S[n]), one or more embodiments may relate to a folded architecture, as in the digital filter 300′ having the architecture exemplified in the circuit block diagram of FIG. 11. The digital filter 300′ includes an input terminal that receives the data signal x[n]. Instead of being passed directly to a DC-track filter circuit 100 as in the embodiments of FIG. 10, the input signal x[n] is passed to a first input of a multiplexer circuit 402 that is controlled by a selection signal sel_ph and can pass the signal x[n] when sel_ph=‘0’. The output of the multiplexer circuit 402 is coupled to the input of the (only) instance 302′ of a DC-track filter circuit 100′.

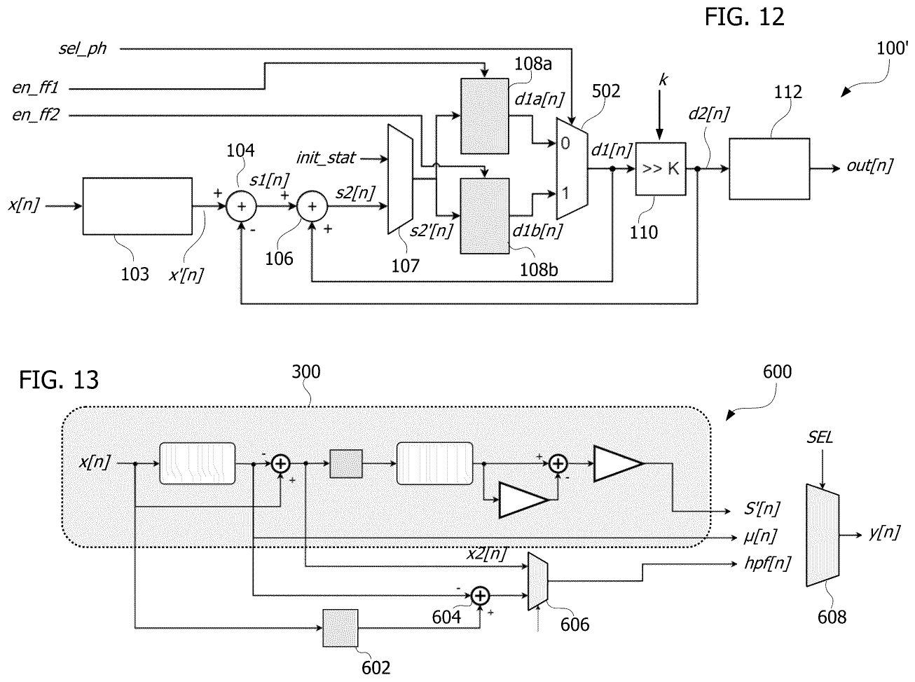

The DC-track filter circuit 100′ is also slightly modified with respect to the DC-track filter circuit 100 of FIG. 6, as will be further described in the following with reference to FIG. 12, but it carries out substantially the same operations (i.e., computation of the exponential average of its input signal with a one-sample delay). The DC-track filter circuit 100′ receives the selection signal sel_ph, as well as two enable signals en_ff1 and en_ff2, whose operation will also be described with reference to FIG. 12.

Signals sel_ph, en_ff1 and en_ff2 may be produced by a control unit (CU) 404. The DC-track filter circuit 100′ produces a respective output signal, carrying out—in a first phase—the operations of block 21 of FIG. 9, so that in this first phase the output signal of the DC-track filter circuit 100′ corresponds to signal x1[n] of FIG. 10. The subtractor circuit 304 and the square operator circuit 306 in the architecture of FIG. 11 operate as described with reference to the embodiments of FIG. 10. It will be noted again that circuits 304 and 306 carry out the operations of block 22 of FIG. 9. Instead of being passed to a second instance 308 of a DC-track filter circuit 100 as in the embodiments of FIG. 10, signal x3[n] from the square operator circuit 306 is passed to a second input of the multiplexer circuit 402, which in turn can pass it to the (only) instance 302′ of the modified DC-track filter circuit 100′ when sel_ph=‘1’ for carrying out—in a second phase—the operations of block 23 of FIG. 9.

Therefore, in the second phase, the output signal of the DC-track filter circuit 100′ corresponds to signal x4[n] of FIG. 10. The right-shifter circuit 310, the subtractor circuit 312 and the optional right-shifter circuit 314 in the architecture of FIG. 11 operate as described with reference to the embodiments of FIG. 10 to produce the output signal S[n] corresponding to the exponential variance of signal x[n], and optionally the scaled signal S′[n]=2^{-M}·S[n]. Again, since the IIR DC-track filter 100′ is used twice, the exponential variance S[n] has a delay of one sample with respect to the input data signal x[n].

Therefore, in the folded implementation of FIG. 11, the IIR DC-track filter circuit is used in two phases for each variance computation. The filter works with 2*(N+1) bits but for the first phase, the N least significant bits may be sufficient to compute the result.

A possible implementation of the modified IIR DC-track filter circuit 100′, suitable for operation in the folded architecture of the filter circuit 300′ of FIG. 11, is exemplified in FIG. 12 and will now be described, mainly by highlighting its differences with respect to the implementation exemplified in FIG. 6 so as to not unnecessarily repeat extensive portions of the present description. Substantially, the modified IIR DC-track filter circuit 100′ includes, in the place of a single memory element 108, two memory elements 108a and 108b (e.g., flip-flops), and an additional multiplexer circuit 502 coupled between the memory elements 108a, 108b and the right-shifter circuit 110. Both memory elements 108a, 108b receive their input signal from the output of multiplexer 107 (or, in embodiments that do not include the multiplexer 107, directly from the adder circuit 106).

Memory element 108a is controlled by the enable signal en_ff1 and produces an output signal d1a[n] that is passed to the first input of multiplexer 502, and memory element 108b is controlled by the enable signal en_ff2 and produces an output signal dib [n] that is passed to the second input of multiplexer 502. Multiplexer 502 is controlled by signal sel_ph and passes either signal d1a[n] or signal dib [n] to the right-shifter circuit 110 as signal d1[n]. Therefore, during the first operation phase of the digital filter 300′ (carrying out the operations of block 21 in FIG. 9), only the first memory element 108a is enabled (e.g., en_ff1=‘1’, en_ff2=‘0’) and the multiplexer 502 is configured to pass to its output the signal d1a[n] coming from its first input terminal (e.g., sel_ph=‘0’). Instead, during the second operation phase of the digital filter 300′ (carrying out the operations of block 23 in FIG. 9), only the second memory element 108b is enabled (e.g., en_ff1=‘0’, en_ff2=‘1’) and the multiplexer 502 is configured to pass to its output the signal dib [n] coming from its second input terminal (e.g., sel_ph=‘1’).

The control unit 404 is configured to handle the sequence of the two computation phases by driving the enable signals en_ff1 and en_ff2 and the selection signal sel_ph of the multiplexers 402 and 502. The enable signals en_ff1 and en_ff2 can be also exploited to set the initial status of each memory element, using the signal init_stat via multiplexer 107 (it will be noted that signal init is not visible in FIG. 12 for the sake of ease of illustration, but can operate in the modified IIR DC-track filter circuit 100′ like in the IIR DC-track filter circuit 100 of FIG. 6).

FIG. 13 is a circuit block diagram example of a possible integration of the digital filter circuit 300 (or 300′) in a (reusable) IP block 600. Substantially, the filter circuit 300 may provide a first output signal S′[n] indicative of the exponential moving variance of signal x[n] (bit-scaled, and with a one-sample delay) from the output of the right-shifter circuit 314, and a second output signal μ[n] indicative of the exponential moving average of signal x[n] (with a one-sample delay) from the output of the first DC-track filter 302. The IP block 600 may include additional circuitry, such as a memory element 602 (e.g., a flip-flop) that stores the value of the input signal x[n], a subtractor circuit 604 that subtracts the moving average signal μ[n] from the stored value of the input signal x[n], and a multiplexer circuit 606 controlled by a configuration register selectable by a user, and configured to pass either signal x2[n] from the output of subtractor 210, or the signal output by the subtractor 604.

Substantially, signal x2[n] is equal to the difference between x[n] and the output of the first instance of the IIR DC-track filter 302. Since the output from filter 302 is the exponential average computed with all the samples up to x[n−1] (i.e., with all the input samples preceding x[n]) and thus amounts to a DC value estimated over all the samples up to x[n−1], signal x2[n] amounts to a high-pass filtering of signal x[n] using an estimated DC value computed over the preceding input samples. The output from subtractor 604, on the other hand, amounts to a high-pass filtering of signal x[n] using an estimated DC value computed over all the input samples, including x[n] (insofar as the input signal is delayed for one sample by the memory element 602). The output of multiplexer 606 is a signal hpf[n] indicative of a high-pass filtering of signal x[n], which can be selected to include or not the last sample x[n] in the computation of the estimated DC value.

Additionally, the IP block 600 may include a square root operator circuit (not visible in FIG. 13) that receives the exponential moving variance S[n] at the input and produces as output a signal indicative of the exponential standard deviation of signal x[n]. The IP block 600 may include an output multiplexer circuit 608 that selects, as the output signal y[n], one of signals S[n], μ[n] and hpf[n] (and possibly also the signal indicative of the standard deviation) as directed by a selection signal SEL, depending on the request of the external circuitry.

One or more embodiments may thus provide one or more of the following advantages: fast computation time of the exponential moving variance of a digital signal, compared to known solutions based on firmware computation; low silicon footprint compared to known hardware IP blocks dedicated to the computation of exponential moving variance; even additional area saving with the folded implementation; re-use of an already validated IP block, that is, the IIR DC-track filter circuit 100; and provision of a multi-purpose hardware (e.g., the IP block 600) that can compute various quantities related to the input digital signal, such as the exponential moving average, the exponential moving variance, a high-pass function, and a low-pass function.

Without prejudice to the underlying principles, the details and embodiments may vary, even significantly, with respect to what has been described by way of example only, without departing from the extent of protection.

The extent of protection is determined by the annexed claims.

What is claimed is:

1. A method of digital signal processing, the method comprising:
receiving a digital input signal;
applying a first infinite impulse response filtering operation to the digital input signal to produce a first filtered signal;
performing a mathematical transformation on a combination of the digital input signal and the first filtered signal to produce a transformed signal;
applying a second infinite impulse response filtering operation to the transformed signal to produce a second filtered signal;
performing a scaling operation on the second filtered signal to produce a scaled signal; and
combining the second filtered signal and the scaled signal to produce a digital output signal indicative of a statistical property of the digital input signal.

2. The method of claim 1, wherein applying the first infinite impulse response filtering operation comprises applying low-pass filtering to the digital input signal to produce the first filtered signal, which is indicative of an exponential moving average of the digital input signal.

3. The method of claim 1, wherein performing the mathematical transformation comprises:
subtracting the first filtered signal from the digital input signal to produce a second intermediate signal; and
computing a square value of the second intermediate signal to produce the transformed signal.

4. The method of claim 1, wherein applying the second infinite impulse response filtering operation comprises applying low-pass filtering to the transformed signal to the second filtered signal, which is indicative of an exponential moving average of the transformed signal.

5. The method of claim 1, wherein performing the scaling operation comprises right-shifting the second filtered signal to produce the scaled signal.

6. The method of claim 1, wherein combining the second filtered signal and the scaled signal comprises subtracting the scaled signal from the second filtered signal to produce the digital output signal.

7. The method of claim 1, wherein applying the first infinite impulse response filtering operation comprises applying low-pass filtering to the digital input signal to produce the first filtered signal;
wherein performing the mathematical transformation comprises subtracting the first filtered signal from the digital input signal to produce a second intermediate signal and computing a square value of the second intermediate signal to produce the transformed signal;
wherein applying the second infinite impulse response filtering operation comprises applying low-pass filtering to the transformed signal to the second filtered signal, which is indicative of an exponential moving average of the transformed signal;
wherein performing the scaling operation comprises right-shifting the second filtered signal to produce the scaled signal; and
wherein combining the second filtered signal and the scaled signal comprises subtracting the scaled signal from the second filtered signal to produce the digital output signal.

8. A digital filter circuit, comprising:
an input terminal configured to receive a digital input signal;
an output terminal configured to provide a digital output signal, the digital output signal being indicative of an exponential moving variance of the digital input signal;
circuits forming a signal processing chain arranged between the input terminal and the output terminal, the signal processing chain being configured to:
apply low-pass filtering to the digital input signal to produce a first intermediate signal indicative of an exponential moving average of the digital input signal;
subtract the first intermediate signal from the digital input signal to produce a second intermediate signal;
compute a square value of the second intermediate signal to produce a third intermediate signal;
apply low-pass filtering to the third intermediate signal to produce a fourth intermediate signal indicative of the exponential moving average of the third intermediate signal;
right-shift the fourth intermediate signal to produce a fifth intermediate signal; and
subtract the fifth intermediate signal from the fourth intermediate signal to produce the digital output signal.

9. The digital filter circuit of claim 8, wherein the signal processing chain is further configured to right-shift the digital output signal to produce a bit-scaled digital output signal.

10. The digital filter circuit of claim 8, wherein the signal processing chain further comprises:
a multiplexer circuit having a first input configured to receive the digital input signal and a second input configured to receive the third intermediate signal, the multiplexer circuit being controlled by a selection signal to pass the digital input signal during a first operation phase and pass the third intermediate signal during a second operation phase;
an infinite impulse response, IIR, filter block coupled to an output of the multiplexer circuit and configured to apply, during the first operation phase, low-pass filtering to the digital input signal to produce the first intermediate signal and to apply, during the second operation phase, low-pass filtering to the third intermediate signal to produce the fourth intermediate signal;
a first subtractor circuit coupled to the input terminal and to an output of the IIR filter block, and configured to subtract the first intermediate signal from the digital input signal to produce the second intermediate signal;
a square operator circuit coupled to an output of the first subtractor circuit and configured to compute the square value of the second intermediate signal to produce the third intermediate signal;
a first right-shifter circuit coupled to the output of the IIR filter block and configured to right-shift the fourth intermediate signal to produce the fifth intermediate signal; and
a second subtractor circuit coupled to the output of the IIR filter block and to an output of the first right-shifter circuit, and configured to subtract the fifth intermediate signal from the fourth intermediate signal to produce the digital output signal.

11. The digital filter circuit of claim 10, further comprising a second right-shifter circuit coupled to an output of the second subtractor circuit and configured to right-shift the digital output signal to produce a bit-scaled digital output signal.

12. The digital filter circuit of claim 10, wherein the IIR filter block comprises:
a subtractor circuit configured to subtract an internal first feedback signal from the input signal of the IIR filter block to produce a first IIR intermediate signal;
an adder circuit configured to add together the first IIR intermediate signal and an internal second feedback signal to produce a second IIR intermediate signal;
a first memory element configured to selectively receive the second IIR intermediate signal, and to pass the second IIR intermediate signal to an output of the first memory element in response to a first enable signal being asserted to produce a respective second feedback signal, the first enable signal being asserted during the first operation phase;
a second memory element configured to selectively receive the second IIR intermediate signal, and to pass the second IIR intermediate signal to an output of the second memory element in response to a second enable signal being asserted to produce a respective second feedback signal, the second enable signal being asserted during the second operation phase;
a further multiplexer circuit configured to receive the second feedback signals from the first and second memory elements, the further multiplexer circuit being controlled by the selection signal to pass the second feedback signal from the first memory element during the first operation phase and pass the second feedback signal from the second memory element during the second operation phase; and
a right-shifter circuit configured to right-shift the digital output signal from the further multiplexer circuit by a number of bits as indicated by a shift-control signal to produce the internal first feedback signal.

13. The digital filter circuit of claim 12, wherein the IIR filter block further comprises:
a sign extension circuit arranged between the respective input terminal and the subtractor circuit, and configured to increase the number of bits of the respective input signal before passing it to the subtractor circuit; and
a truncation circuit arranged between the respective right-shifter circuit and a respective output terminal, and configured to truncate the number of bits of the internal first feedback signal before passing it to the respective output terminal.

14. The digital filter circuit of claim 12, wherein the IIR filter block comprises:
a third multiplexer circuit arranged between the output of the adder circuit and inputs of the first and second memory elements, the third multiplexer circuit being controlled by a control signal to pass to the first and second memory elements either the second IIR intermediate signal or a register initialization signal.

15. A system-on-chip, comprising:
an analog-to-digital converter;
the digital filter circuit according to claim 8, the input terminal of the digital filter circuit coupled to an output of the analog-to-digital converter; and
an ASK demodulator circuit having an input coupled to the output terminal of the digital filter circuit.

16. A digital filter circuit comprising:
an input terminal configured to receive a digital input signal;
a first infinite impulse response (IIR) filter block coupled to the input terminal and configured to apply low-pass filtering to the digital input signal to produce a first intermediate signal;
a first subtractor circuit coupled to the input terminal and to an output of the first IIR filter block, and configured to subtract the first intermediate signal from the digital input signal to produce a second intermediate signal;
a square operator circuit coupled to an output of the first subtractor circuit and configured to compute a square value of the second intermediate signal to produce a third intermediate signal;
a second IIR filter block coupled to an output of the square operator circuit and configured to apply low-pass filtering to the third intermediate signal to produce a fourth intermediate signal;
a first right-shifter circuit coupled to an output of the second IIR filter block and configured to right-shift the fourth intermediate signal to produce a fifth intermediate signal; and
a second subtractor circuit coupled to an output of the second IIR filter block and to an output of the first right-shifter circuit and configured to subtract the fifth intermediate signal from the fourth intermediate signal to produce a digital output signal that is indicative of an exponential moving variance of the digital input signal.

17. The digital filter circuit of claim 16, further comprising a second right-shifter circuit coupled to the output of the second subtractor circuit and configured to right-shift the digital output signal to produce a bit-scaled digital output signal.

18. The digital filter circuit of claim 16, wherein the first and second IIR filter blocks each comprise:
a subtractor circuit configured to subtract a respective internal first feedback signal from the respective input signal to produce a respective first IIR intermediate signal;
an adder circuit configured to add together the respective first IIR intermediate signal and a respective internal second feedback signal to produce a respective second IIR intermediate signal;
a memory element configured to selectively receive the respective second IIR intermediate signal, and to pass the respective second IIR intermediate signal to an output of the memory element in response to an enable signal being asserted to produce the respective second feedback signal; and
a right-shifter circuit configured to right-shift the respective second feedback signal by a number of bits as indicated by a shift-control signal to produce the respective internal first feedback signal.

19. The digital filter circuit of claim 18, wherein the first and second IIR filter blocks each further comprise:
a sign extension circuit arranged between the respective input terminal and the subtractor circuit, and configured to increase the number of bits of the respective input signal before passing it to the subtractor circuit; and
a truncation circuit arranged between the respective right-shifter circuit and a respective output terminal, and configured to truncate the number of bits of the respective internal first feedback signal before passing it to the respective output terminal.

20. The digital filter circuit of claim 18, wherein the first and second IIR filter blocks each comprise a multiplexer circuit arranged between the output of the adder circuit and the input of the memory element, the multiplexer circuit being controlled by a control signal to pass to the memory element either the respective second IIR intermediate signal or a register initialization signal.
